(19) United States
(12) Patent Application Publication
(10) Pub. No.: US 2009/0023101 A1
(43) Pub. Date: Jan. 22, 2009

(54) LITHOGRAPHY TRACK SYSTEMS AND METHODS FOR ELECTRONIC DEVICE MANUFACTURING

(75) Inventor: Michael C. Smayling, Fremont, CA (US)

Correspondence Address: DUGAN & DUGAN, PC, 245 Saw Mill River Road, Suite 309, Hawthorne, NY, 10532, US

(73) Assignee: APPLIED MATERIALS, INC., Santa Clara, CA (US)

(21) Appl. No.: 12/174,457

(22) Filed: Jul. 16, 2008

Related U.S. Application Data
(60) Provisional application No. 60/950,115, filed on Jul. 16, 2007.

(51) Int. Cl. G03F 7/22; B05C 13/00; G03B 27/42

(52) U.S. Cl. 430/325; 118/500; 355/53

(57) ABSTRACT

The present invention provides systems, methods, and apparatus for processing a lot of substrates in a lithography track system with an integrate metrology sensor. The invention includes performing a coating process on substrates; transferring the substrates to a stepper for alignment and exposure; transferring the substrates to a post-exposure bake chamber for bake; and performing metrology on the substrates in the lithography track system. The invention may further include automatically reworking substrates in an integrated rework chamber within the lithography track system. Numerous other aspects are provided.

### CROSS-REFERENCE TO RELATED APPLICATIONS

The present invention claims priority to U.S. Provisional Patent Application No. 60/950,115, filed Jul. 16, 2007, and entitled “LITHOGRAPHY TRACK SYSTEM FOR ELECTRONIC DEVICE MANUFACTURING” which is hereby incorporated by reference herein for all purposes.

### FIELD OF THE INVENTION

The present invention relates generally to electronic device manufacturing systems, and more particularly to lithography tracks in such systems.

### BACKGROUND OF THE INVENTION

Semiconductor device geometries have dramatically decreased in size since such devices were first introduced several decades ago. As device geometries have become more dense, reductions in the spacing between device elements has occurred. The minimum line widths achieved using semiconductor lithography systems, sometimes referred to as a critical dimension (CD) have decreased over time.

Lithography or photolithography generally refers to processes for transferring patterns between a mask layer and a semiconductor substrate. In lithography processes for electronic device fabrication, a silicon substrate is typically uniformly coated with a photosensitive material, referred to as a photoresist, for example, in a cluster tool. A scanner/stepper tool may be used to selectively expose the photoresist to some form of electromagnetic radiation to generate a circuit pattern corresponding to an individual layer of the integrated circuit (IC) device to be formed on the substrate surface. Generally, the photoresist film is selectively exposed using a mask layer that preferentially blocks a portion of the incident radiation. Other alternative or additional methods may be employed. The portions of the photoresist film that are exposed to the incident radiation become more or less soluble depending on the type of photoresist that is utilized. In some systems, a developing step dissolves the more soluble regions of the photoresist film, producing a patterned photoresist layer corresponding to the mask layer used in the exposure process.

The precision with which the patterns are developed on the semiconductor substrate impacts the CDs present on the substrate, likely impacting device performance. Overdevelopment may result in an increase in line widths, whereas underdevelopment may result in portions of the photoresist layer not being removed as desired. This is one example of a part of the lithography process that may result in the need for rework. Many others exist. Various methods have been used, for example, to determine the endpoint of the developer process and/or to identify devices formed on the substrate whose dimensions are outside of the specified/acceptable range and thus require rework. However, these methods are typically manual, significantly impact the throughput of the system, and typically require sample substrates to be removed from the system to perform one or more metrology and rework processes. Therefore, there is a need in the art for improved systems for detecting the need for re-work and improved methods of automating the same.

### SUMMARY OF THE INVENTION

In some embodiments, the present invention provides a system that includes a lithography track adapted to process a substrate; and an integrated metrology sensor disposed within the lithography track.

In other embodiments, the present invention provides a lithography track that includes a coating chamber; a post-exposure bake chamber adjacent the coating chamber; and an integrated metrology sensor disposed within the lithography track.

In yet other embodiments, the present invention provides a method of processing a lot of substrates in a lithography track system. The method includes performing a coating process on a substrate; transferring the substrate to a stepper for alignment and exposure; transferring the substrate to a post-exposure bake chamber for bake; and performing metrology on the substrate in the lithography track system.

Numerous other aspects are provided in accordance with these and other aspects of the invention. Other features and aspects of the present invention will become more fully apparent from the following detailed description, the appended claims and the accompanying drawings.

### BRIEF DESCRIPTION OF THE DRAWINGS

FIG. 1 is flow chart depicting a prior art method of processing a substrate.

FIG. 2 is flow chart depicting an example method of processing a substrate according to some embodiments of the present invention.

FIG. 3 is a block diagram that schematically depicts an example lithography track system according to some embodiments of the present invention.

### DETAILED DESCRIPTION

Manuel rework process flows are well known in the electronic device manufacturing industry. However, due to various factors, automation of rework processes remains commercially unavailable. The present invention overcomes a number of these factors to allow rework processes to be automated in lithography tracks. Using integrated, in situ metrology, the present invention provides the capability of automatically reworking test substrates or other substrates which have automatically been identified as, for example, not meeting critical dimensions (CD) or not meeting overlay specifications.

In some embodiments, the present invention provides a lithography track that includes one or more integrated metrology sensors such that in-place analysis of the substrates being processed may be made without having to transfer the substrates to a separate metrology tool. The present invention further provides process control software, operable to run on either a controller of the lithography track or a separate host controller, that is adapted to determine whether a photoresist pattern should be reworked or meets specifications. This metrology determination may be applied to test substrates to greatly reduce overall substrate lot cycle time and thus, increase overall throughput. In some embodiments, the metrology determination may be applied to any or all substrates being processed in the lithography track of the present invention.

The present invention overcomes a number of problems with prior art rework processes. Test substrates, often prepared with a “focus-exposure” matrix (FEM), need to be reworked. This rework is conventionally done in other tools or equipment and requires that the remaining substrates in the lot associated with the test substrate must wait for the test substrate, or that the test substrate gets patterned later and catches up with the associated lot. In either case, extra handling is required and the process flow is complicated in the manufacturing execution system (MES). Further, in conventional systems, metrology (e.g., CD and overlay) measurements are not typically made on other substrates in the lot associated with the test substrate. However, using the lithography track with integrated in-situ metrology of the present invention, the data required to make pass/fail decisions is easily and quickly acquired and made available for such use. The present invention further includes an in-situ rework capability integrated with the track to allow rework without the extra handling and flow complications of conventional manual process flows.

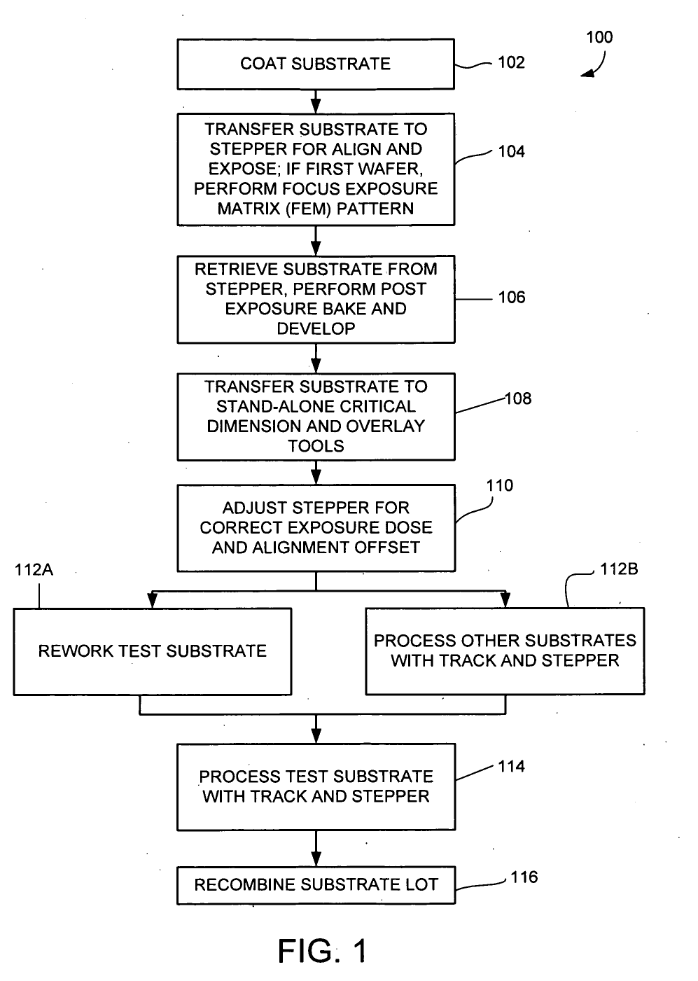

Turning to FIG. 1, an example of a typical prior art lithography process 100 is depicted. In step 102, a coating process (e.g., BARC (i.e., bottom anti-reflective coating), resist, top coat, etc.) is performed. In Step 104, the substrate is transferred to a stepper for alignment and exposure. If the substrate is the first in the lot, a FEM pattern may be formed. In step 106, the substrate is retrieved from the stepper, post-exposure bake (PEB) is performed, and the substrate is developed. In step 108, the substrate is transferred to stand-alone metrology tools to measure CD and overlay of the pattern. In step 110, the stepper is adjusted for the correct exposure dose and alignment offset based on the metrology. In step 112A, the test substrate is reworked (e.g., ashing and/or wet clean processes are applied). Alternatively, if the substrate is one of the remaining substrates in the lot associated with the test substrate, in step 112B, the substrate is processed by the track and the stepper. In step 114, the test substrate is processed by the track and the stepper. Thus, the prior art method of reworking the test substrate (or any other substrates in the associated lot) requires additional handling and cycle time because either the performance of track and scanner processing step 114 on the test substrate must wait or step 112B, processing of the other substrates in the associated lot, must wait. In step, 116, the substrate lot is recombined and is moved to the next step in the process flow.

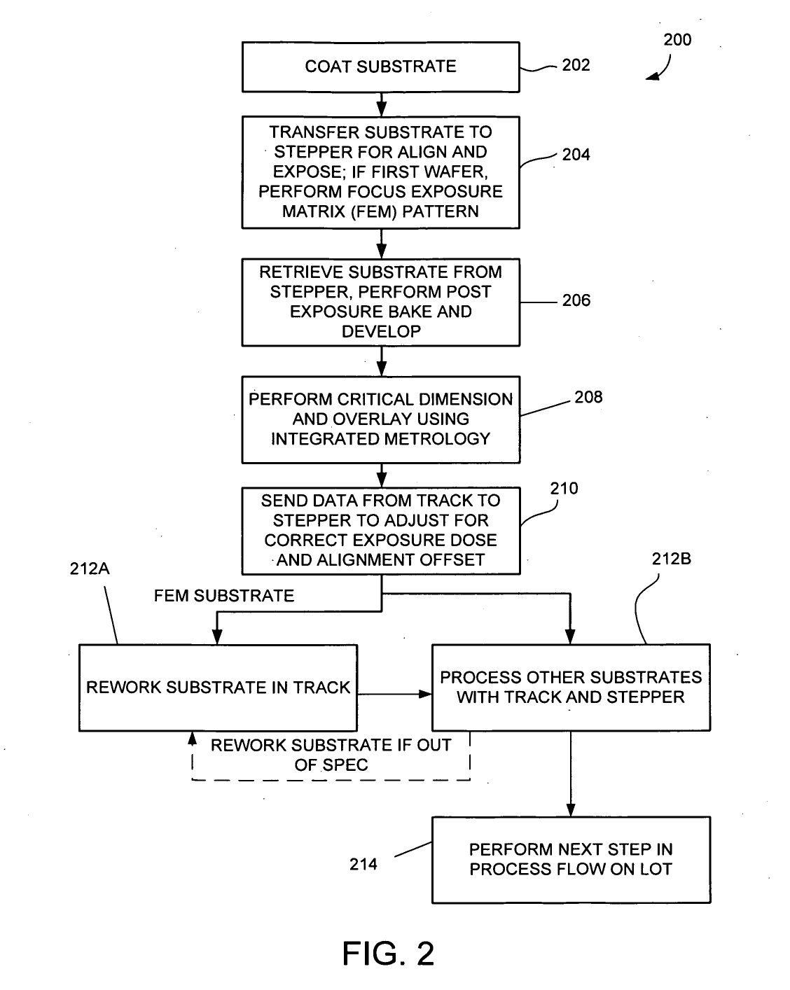

Turning to FIG. 2, an example of a lithography process 200 according to embodiments of the present invention is depicted. In step 202, a coating process (e.g., BARC, resist, top coat, etc.) is performed. In Step 204, the substrate is transferred to a stepper for alignment and exposure. If the substrate is the first in the lot, a FEM pattern may be formed. In step 206, the substrate is retrieved from the stepper, PEB is performed, and the substrate is developed. In step 208, CD and overlay of the pattern is measured within and by the track using integrated metrology sensors. In step 210, the track sends the stepper the data (determined from the integrated metrology) to adjust for the correct exposure dose and alignment offset. In step 212A, without being separated from the associated lot, the test substrate is reworked (e.g., ashing and/or wet clean processes are applied) in the track using an integrated rework system and then, in step 212B, processed by the track and the stepper. CD and overlay are measured using the integrated meteorology. Alternatively, if the substrate is one of the remaining substrates in the lot associated with the test substrate, the rework step 212A is bypassed and in step 212B, the substrate is processed by the track and the stepper. CD and overlay are measured on all substrates using the integrated meteorology. In step 214, the substrate lot is moved to the next step in the process flow.

Thus, by using the integrated metrology and automated rework chambers, the overall cycle time may be reduced and less handling of the substrates is required as compared with conventional processes.

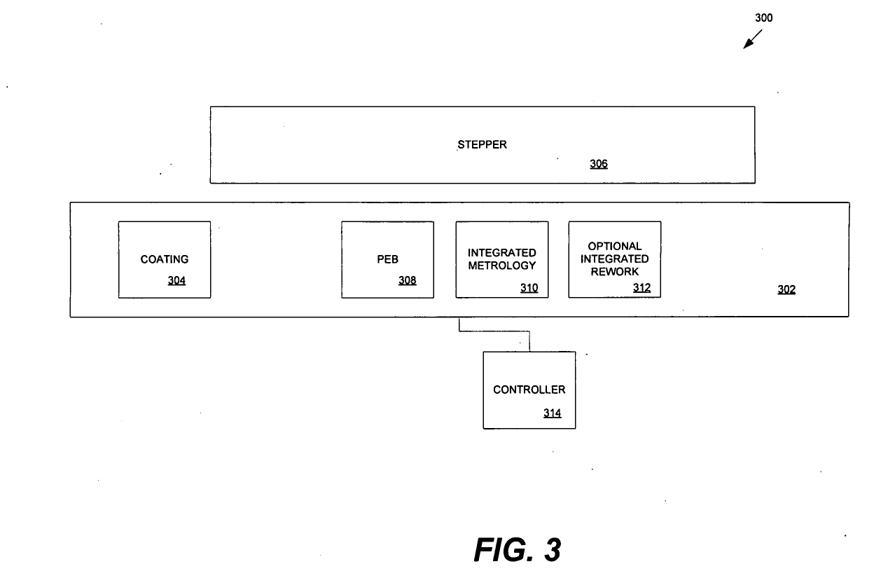

Turing to FIG. 3, an example lithography track system 300 according to embodiments of the present invention is depicted. An inventive lithography track system 300 may include a lithography track 302 which includes a coating processing chamber 304, access to a stepper 306, a post-exposure bake chamber 308, an integrated metrology chamber 310, and an optional integrated rework chamber 312. A controller 314 is coupled to the lithography track system 300 and operative to use the data from the integrated metrology chamber 310 to control or adjust the stepper 306 and/or other components.

In some embodiments for example, the integrated metrology chamber 310 may include and support a scatterometer of the spectroscopic reflectometer type. This device uses a light source to supply a high-power, broadband, well-collimated beam which is directed to a beam splitter, which reflects the beam towards the substrate to be measured. A microscope objective lens focuses the beam onto the substrate and collects the reflected light, directing it through the beamsplitter to a mirror, which reflects the light to a grating. The grating disperses the light onto a detector, e.g., a cooled CCD array. The output of the CCD array represents a spectrum of the reflected light, i.e. a measurement of intensity as a function of wavelength, which can be used to deduce parameters of a structure on the substrate, e.g. the linewidth of a grating, in a known manner, for example by comparison with a library of measurements form test structures or spectra calculated by simulation.

In operation, the present lithography track system 300 may be used to perform the methods of the present invention. Although not shown, one or more robots and/or substrate handling devices operating under the direction of the controller 314 may be included in the lithography track system 300. A coating process (e.g., BARC, resist, top coat, etc.) is performed on the substrates in the coating processing chamber 304. The substrates are then each individually transferred to the stepper 306 for alignment and exposure. As indicated above, if the particular substrate being processed is the first in the lot, a FEM pattern may be formed. The substrate is then retrieved from the stepper 306, PEB is performed in the post-exposure bake chamber 308, and the substrate is developed.

Next, CD and overlay of the pattern is measured within and by the track 302 using integrated metrology sensors in the integrated metrology chamber 310. The track 302 sends the stepper 306 the data (determined from the integrated metrology) to adjust for the correct exposure dose and alignment offset. Without being separated from the associated lot, the test substrate is reworked (e.g., ashing and/or wet clean processes are applied) in the track 302 using an integrated rework system 312 and then, processed by the track 302 and the stepper 306. CD and overlay are measured using the integrated meteorology chamber 310. Alternatively, if the substrate is one of the remaining substrates in the lot associated with the test substrate, rework system 312 is bypassed and the substrate is processed by the track 302 and the stepper 306. CD and overlay are measured on all substrates using the integrated meteorology chamber 310. In some embodiments, metrology sensors may be disposed in additional locations along the track 302 and/or stepper 306 in addition to within the integrated meteorology chamber 310.

The foregoing description discloses only exemplary embodiments of the invention. Modifications of the above disclosed apparatus and method which fall within the scope of the invention will be readily apparent to those of ordinary skill in the art.

Accordingly, while the present invention has been disclosed in connection with exemplary embodiments thereof, it should be understood that other embodiments may fall within the spirit and scope of the invention, as defined by the following claims.

The invention claimed is:

1. A system comprising:
a lithography track adapted to process a substrate; and
an integrated metrology sensor disposed within the lithography track.

2. The system of claim 1 further comprising an integrated metrology chamber adapted to support the integrated metrology sensor.

3. The system of claim 2 wherein the lithography track includes a post-exposure bake chamber and wherein the integrated metrology chamber is disposed adjacent the post-exposure bake chamber.

4. The system of claim 1 further comprising an integrated rework chamber disposed within the lithography track.

5. The system of claim 4 wherein the lithography track includes a post-exposure bake chamber and an integrated metrology chamber adapted to support the integrated metrology sensor, and wherein the integrated rework chamber is disposed adjacent the integrated metrology chamber.

6. The system of claim 5 further including a controller coupled to the lithography track and adapted to direct the integrated rework chamber to process substrates based on data from the integrated metrology chamber.

7. The system of claim 6 wherein the lithography track is adapted to process a lot of substrates without separating an associated test substrate from the lot while the test substrate is reworked.

8. A lithography track comprising:
a coating chamber;
a post-exposure bake chamber adjacent the coating chamber; and
an integrated metrology sensor disposed within the lithography track.

9. The lithography track of claim 8 further comprising an integrated metrology chamber adapted to support the integrated metrology sensor.

10. The lithography track of claim 9 wherein the integrated metrology chamber is disposed adjacent the post-exposure bake chamber.

11. The lithography track of claim 8 further comprising an integrated rework chamber disposed within the lithography track.

12. The lithography track of claim 11 wherein the lithography track includes an integrated metrology chamber adapted to support the integrated metrology sensor and wherein the integrated rework chamber is disposed adjacent the integrated metrology chamber.

13. The lithography track of claim 12 further including a controller coupled to the lithography track and adapted to direct the integrated rework chamber to process substrates based on data from the integrated metrology chamber.

14. The lithography track of claim 13 wherein the lithography track is adapted to process a lot of substrates without separating an associated test substrate from the lot while the test substrate is reworked.

15. A method of processing a lot of substrates in a lithography track system, the method comprising:
performing a coating process on a substrate;
transferring the substrate to a stepper for alignment and exposure;
transferring the substrate to a post-exposure bake chamber for bake; and
performing metrology on the substrate in the lithography track system.

16. The method of claim 15 further comprising adjusting the stepper based on the metrology performed on the substrate in the lithography track system.

17. The method of claim 16 further comprising processing additional substrates of the lot in the adjusted stepper.

18. The method of claim 15 further comprising reworking the substrate in the lithography track system without separating the substrate from the lot.

19. The method of claim 18 wherein reworking the substrate in the track includes using an integrated rework system disposed in the lithography track system.

20. The method of claim 15 wherein the metrology is performed using an integrated metrology sensor disposed in the lithography track system.
